(19) United States
(12) Patent Application Publication
(10) Pub. No.: US 2006/0232347 A1
(43) Pub. Date: Oct. 19, 2006

(54) Gunn diode

(75) Inventor: Keith David Newsome, Lincoln (GB)

Correspondence Address: VENABLE LLP, P.O. BOX 34385, WASHINGTON, DC, 20045-9998, US

(73) Assignee: E2V Technologies (UK) Limited, Chelmsford (GB)

(21) Appl. No.: 11/394,212

(22) Filed: Mar. 31, 2006

(30) Foreign Application Priority Data
Mar. 31, 2005 (GB) 0506588.3

(51) Int. Cl. H03B 9/12

(52) U.S. Cl. 331/107 G

(57) ABSTRACT

A Gunn diode having axis A consists of appropriately doped layers which, when a suitable voltage is applied, cause a space charge 6 to traverse a transit region 7 at a microwave frequency. In a typical known Gunn diode, the layers 4, 5 and 7 to 9 extend across the full diameter of the diode, and the space charge 6 is usually depicted as being disc-shaped. There is the disadvantage that the d.c. component of the Gunn effect current associated with a desired harmonic frequency causes undesirable heating. According to the invention, the area through which the current can flow through the elongate structure is tailored to favour the harmonic over the d.c. component, utilising the skin effect. Several ways of doing this are described, notably by making the core of the elongate portion non-conducting, for example, by ion implantation or by its removal by etching.

### CROSS-REFERENCE TO RELATED APPLICATION

This application claims the priority of British Patent Application No. 0506588.3 filed on Mar. 31, 2005, the subject matter of which is incorporated herein by reference.

### BACKGROUND OF THE INVENTION

This invention relates to Gunn diodes, which are also known as transferred electron devices.

Such devices are used for producing low cost and compact sources of microwave oscillations, for example, for use in radar used in automotive adaptive cruise control (A Compact 77 Ghz Transceiver Module Using G3D Diode Technology for Automotive Applications, by Nigel Priestley and Brian Prime, Advanced Microsystems for Automotive Applications 2003, edited by Jurgen Valldorf and Wolfgang Gessner, Springer (ISBN 3-540-00597-8).

FIG. 1 is a sectional view through the axis A of a known Gunn diode, the diode being symmetrical about its axis. The diode consists of a mass indicated generally by the reference 1 of Gallium Arsenide (GaAs) sandwiched between two gold contacts, 2,3, one of which 3 acts as a heat sink. The Gunn diode is made from a wafer of gallium arsenide on which are grown epitaxial layers, before the contacts are applied and the wafer etched so as to separate the wafer into individual Gunn diodes 1. The tapered shape of the Gunn diode (referred to as a mesa) is characteristic of the wet etching process, and arises because the top of the structure is exposed to the etchant for longer than the material at the bottom. Other methods for defining the Gunn diode, for example, implant isolation (also referred to as ion implantation or ion isolation) are known for defining the electrically-active areas (Implant isolation scheme for current confinement in graded-gap Gunn diodes, by S Hutchinson, J Stephens, M Carr and M J Kelly, Electronics Letters, 25^{th} Apr. 1996, Vol 32 No 9), wherein a cylindrical electrically active area is produced instead of the wet etch tapering shape by bombardment of the gallium arsenide wafer with a cylinder of e.g. protons using contacts metallised on the wafer as an implant mask. The individual diodes are then separated from each other.

Referring to FIG. 2, which is a schematic representation of the individual layers (not to scale) of the wet-etched Gunn diode, and in which the tapering shape and the contacts of FIG. 1 are not illustrated for simplicity, the mass 1 is n-type gallium arsenide. The substrate 4 and contact layer 5, forming contact regions adjacent the gold contacts 2,3, are highly doped (n+) for good conductivity. Successive regions of space charge called “domains” 6 are swept along a transit region 7 and flow out of the anode connected to the substrate via a buffer layer 8. This is doped (n+), and provides a base for an accurate thickness of transit region 7 to be grown. To assist in enabling the domains to form, region 9 is doped to provide hot electron injection.

An applied voltage between the anode and the cathode causes electrons to flow towards the anode under the voltage gradient. Electrons raised to a higher potential level have reduced mobility and travel at a slower rate, causing the formation of the domain “bunches”. The frequency is largely determined by the time taken for the domains to be swept through the transit region 7 before being annihilated at the anode.

The power generated by the Gunn diode, often held to the desired frequency by a resonator, depends on the current through the Gunn diode, and hence its diameter. A typical Gunn diode current is 600 mA at a voltage bias of 5.5 volts, but the length of the transit region may be a fraction of a millimetre so the voltage gradient developed across the region is in the range of Kilovolts per millimetre at which the formation of domains starts. The efficiency of such harmonic Gunn diode oscillators can be as low as 1% to 2%, resulting in the generation of heat which needs to be dissipated.

In the interests of removing this heat, an annular Gunn diode has been proposed, with the central region hollow (GB Patent No. 1 232 643) or filled with conducting dielectric (Russian Patent No. 2 054 213).

However, the Applicants have appreciated that the current density is not uniformly distributed over the cross-sectional area of the diode, because of the skin effect. FIG. 3 is a graph of current density against depth into the surface of the Gunn diode, taken through the transit region. The three plots represent, respectively, the d.c. component (the flat plot) of the Gunn effect current, the fundamental (sometimes termed “the first harmonic”), the middle plot, and the second harmonic (twice the fundamental), the most dished plot.

### SUMMARY OF THE INVENTION

The invention provides a Gunn diode arranged to be resonant at a fundamental frequency, comprising an elongate portion along which current can flow having contacts at each end, the core of the elongate portion being substantially non-conducting over at least a part of the length of the elongate portion, in which the Gunn diode is also arranged to be resonant at a harmonic of the fundamental frequency.

The invention also provides a Gunn diode arranged to be resonant at a fundamental frequency, comprising an elongate portion along which current can flow having contacts at each end, current flow being confined in use to a strip-like region region over at least a part of the length of the elongate portion, in which the Gunn diode is also arranged to be resonant at a harmonic of the fundamental frequency.

The invention permits the current flow area available for the d.c. component of the current through the Gunn diode to be restricted to a much greater extent than that for the harmonic frequency component, as a result of the skin effect.

In the case of the Gunn diode having the non-conducting core, the core, which advantageously extends the full length of the Gunn diode, may be made non-conducting by being etched away, or by means of ion implantation (also termed ion isolation or implant isolation). The conducting region may be an annular region, which could be hollow cylindrical, surrounding the non-conducting core. Thermally conducting material in the core may be provided.

In the case of a Gunn diode in which current flow is confined to a strip-like region, the length of the strip-like region could be at least three times the width.

The invention is applicable to Gunn diodes resonant at a second harmonic (twice the fundamental), as well as to diodes resonant at higher harmonics, that is, multiples of the fundamental greater than two, for example, third, fourth or higher. It is necessary that the Gunn diode undergoes resonance at the fundamental as well, otherwise the resonance at the second or higher harmonic could not be supported, but means, such as a resonator, may be provided to hold the resonance at the fundamental, so that it is not transmitted. Thus, for example, the resonator at the fundamental may be used in association with the Gunn diode in a tubular transmission line (waveguide) whose cut-off is above the fundamental frequency, or in association with a transmission line such as a microstrip structure or a coaxial line, whose dimensions are such that the fundamental will not propagate due to a filtering action.

### BRIEF DESCRIPTION OF THE DRAWINGS

Ways of carrying out the invention will now be described in greater detail, by way of example, with reference to the accompanying drawings, in which:

FIG. 1 is an axial section of a known Gunn diode;

FIG. 2 is an axial cross-section of the Gunn diode shown in FIG. 1, the contacts and the taper not being illustrated;

FIG. 3 is a plot of current density against depth for the d.c.component, the fundamental (first harmonic) and the second harmonic component of the Gunn effect current through the transit region of the known diode of FIG. 2;

FIG. 4 is an axial cross-section of a first Gunn diode in accordance with the invention;

FIG. 5 is a plot of current density against depth for the d.c. component, the fundamental (first harmonic) and the second harmonic component of the Gunn effect current through the transit region of the diode shown in FIG. 4;

FIG. 6 is an axial cross-section of a second Gunn diode in accordance with the invention;

FIG. 7 is an axial cross-section of a third Gunn diode in accordance with the invention;

FIG. 8 is a schematic front view of a third Gunn diode in accordance with the invention;

FIG. 9 is a top plan view of the third Gunn diode;

FIG. 10 illustrates a first stage in the manufacture of the Gunn diodes of the invention from a GaAs wafer;

FIG. 11 illustrates a subsequent stage in the manufacture of one of the individual Gunn diodes;

FIG. 12 is a top plan view of the part-manufactured Gunn diode illustrated in FIG. 11;

FIG. 13 is an axial section of a finished Gunn diode according to the invention (for illustrative purposes and not to scale);

FIG. 14 is a flow chart for manufacture of the Gunn diodes; and

FIG. 15 is a sectional view of the Gunn diode of FIG. 13 mounted in a waveguide and arranged to transmit energy at a second harmonic frequency.

### DETAILED DESCRIPTION OF THE INVENTION

Like parts are given like reference numerals through all the drawings.

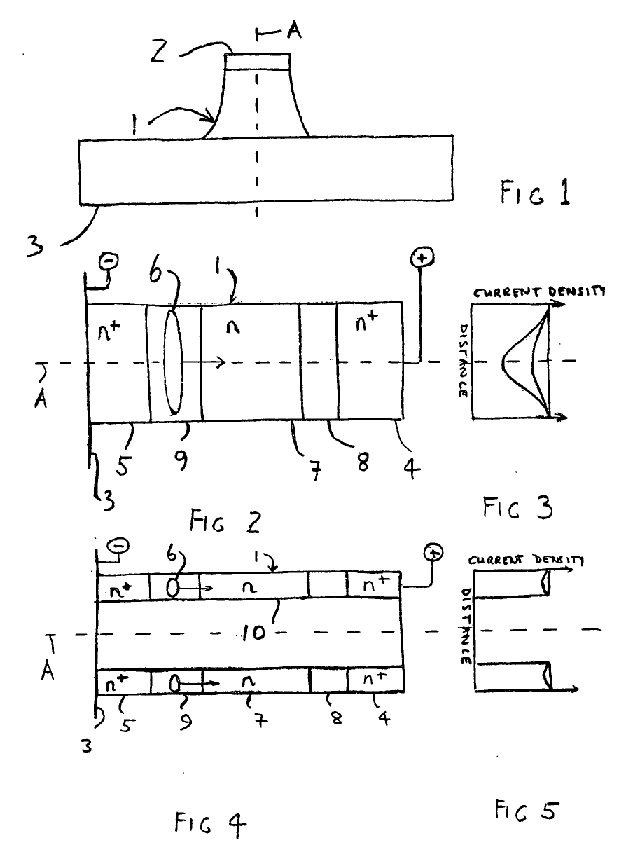

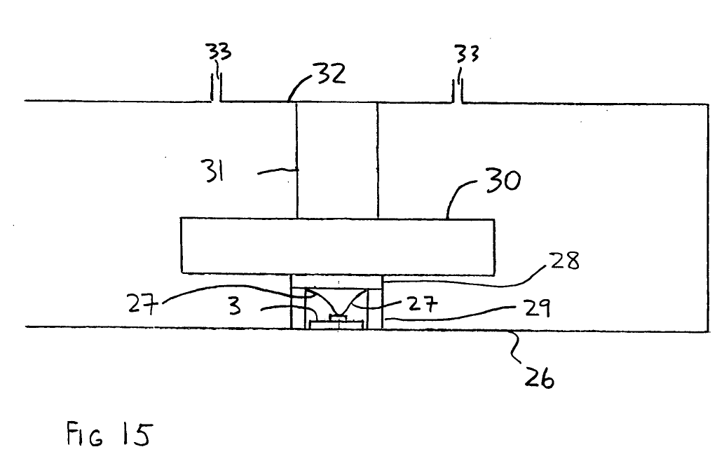

Referring to FIG. 4 of the accompanying drawings, the first Gunn diode comprises a gallium arsenide elongate portion 1 having the same tapered external shape as the known Gunn diode shown in FIG. 1 and the same doped layers 4, 5, 7 to 9 as shown in the simplified drawing of FIG. 2. Also, the Gunn diode of FIG. 4 has top 2 and bottom 3 gold contacts at its ends (not shown in FIG. 4 but shown in FIG. 13), the bottom contact forming a heat sink.

The core 10 of the Gunn diode is non-conducting. The effect of this, compared to the known Gunn diode of FIG. 2, is that the conducting area is annular, that is, ring-like, along the length of the elongate portion 1. The space charge (domain) 6 which drifts through the transit region 7 is shaped like a torus.

The central core is rendered non-conducting by implant isolation (ion implantation), that is, by bombardment of the elongate portion 1 with ions, for example, oxygen ions or hydrogen ions, the contact 2 being shaped with a central aperture 2a (FIG. 13), and used as a mask for this purpose. Referring to FIG. 13, the conducting region defined after the implant ionisation process is the hollow cylindrical region between cylinder 10 (defined by aperture 2a) and cylinder 10a (defined by the outer periphery of the top contact 2). The core 10 and the flared sheath outside the cylinder 10a are made non-conducting by the implantation.

It is also within the scope of the invention for the non-conducting core region to be created by being chemically etched away, leaving a hollow core. In this case, the entire volume of the hollow flared remainder is conducting. The core may not be cylindrical due to the etching process, but may be somewhat tapered.

Referring to FIG. 5, the Gunn effect current can only pass through the hollow cylindrical region, including the direct current component, and fundamental (first harmonic) and second harmonic components. It will be seen from FIG. 3 that fundamental (first harmonic) and second harmonic current falls off with distance into the elongate portion at more or less the same rate over the outer thickness of the elongate portion, so the current density for each is represented in FIG. 5 by the same shallow depression. (The variation of current density of the components of the Gunn effect current is shown in FIG. 5 for the transit region; the fall-off with depth is more pronounced in regions of higher conductivity). Comparing FIG. 5 with FIG. 3, it can clearly be seen that the central non-conducting region has little effect on the second harmonic current density, since this was carried predominantly in the outer surface region of the elongate portion, but has a significant effect on the d.c. component of the Gunn effect current. Thus, the same second harmonic current can be produced for less d.c. component, and the Gunn diode can therefore be run at lower power.

For example, a Gunn diode with a diameter of elongate portion of 140 μm (micrometres) at the end adjacent contact 2 could be expected to conduct typically around 2 amps. A Gunn diode according to the invention having a central isolated region of diameter 120 μm at the end adjacent contact 2 could be expected to conduct a little over half an amp, without any significant effect on the second harmonic current, representing a significant increase in efficiency. Also, it is easier to remove thermal energy from the diode because of the non-conducting core.

In fact, good results will be achieved with a central isolated region having a maximum diameter (the diameter will be uniform when defined by ion implantation and tapering when defined by etching) within the range of from 50% to 95% of the diameter of the elongate portion at the end adjacent contact 2, preferably within the range of from 80% to 90%.

The Gunn diode may be a graded gap Gunn diode (as described, for example in the Advanced Microsystems for Automotive Applications paper referred to above), but this is not essential, nor is it essential for the Gunn diode to be of gallium arsenide. Other materials in which the Gunn effect can be displayed, such as Indium Phosphide or Gallium Nitride may be used.

The isolated, hollow cylindrical, region preferably extends the full length of the elongate portion, but this is not essential. Equally, while the conductive region is the space between two circular regions, this is not essential. Thus, for example, referring to FIG. 7, the outer periphery of the elongate portion may be provided with corrugations 11, and the inner periphery of the hollow cylindrical region may likewise be non-circular.

Nor is the invention restricted to current being confined to an annular region. For example, referring to FIGS. 6, 8 and 9, the current may be confined to a strip-like region, for example, a region of which the length is at least three times the width. In FIG. 6 the strip-like region 12 extends in a peripheral direction, but differs from the embodiment of FIG. 4 in that the strip-like region is not continuous around the periphery of the elongate portion, so that there is a non-conducting portion 13 at one position around the circumference of the elongate portion.

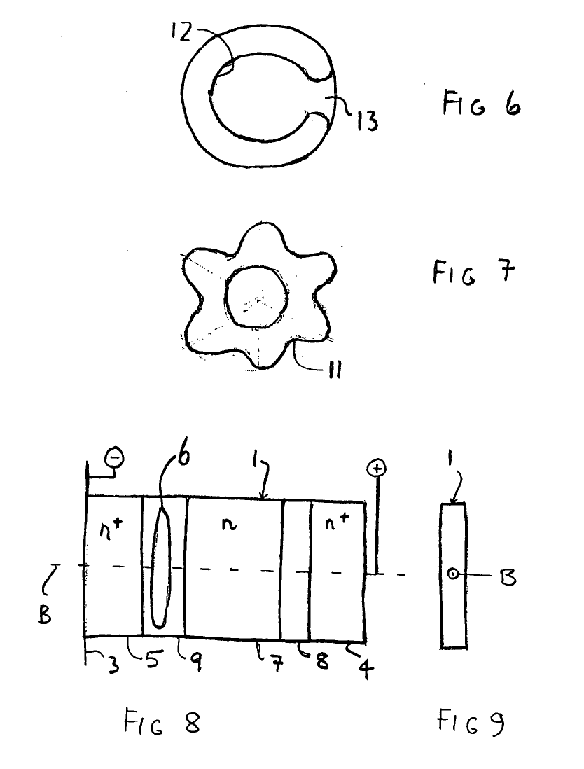

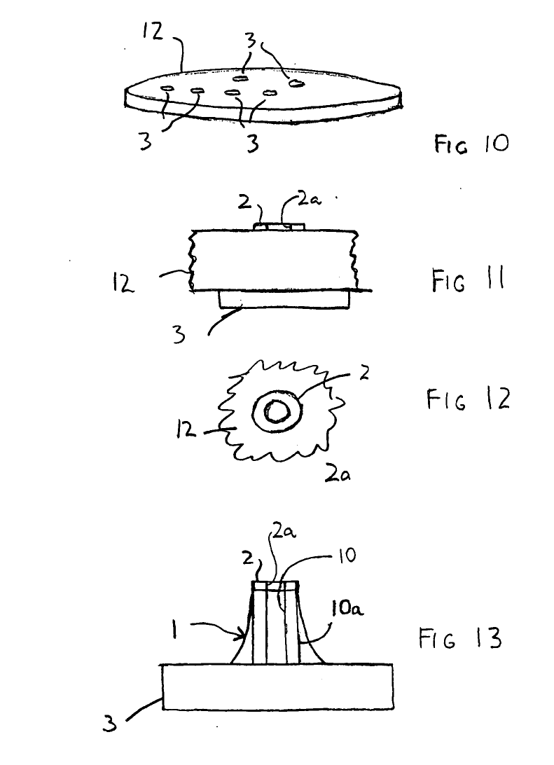

In FIGS. 8 and 9, the strip-like region is straight, so that the Gunn diode is in the form of a thin elongate slab having axis B, which is seen end-on in FIG. 9. The top and bottom contacts are not shown, but would be above and below the plane of the page in the view of FIG. 9. In this embodiment, there is no non-conducting region, but the d.c. component of current is reduced compared to the second harmonic component simply because the elongate portion is shallow in depth over its whole length. A feature of such a configuration is that the radiation pattern would not be uniform around the circumference of the elongate portion.

All the preceding embodiments of the invention have described a Gunn diode which is designed to produce a second harmonic, that is, twice the fundamental or first harmonic. However, the invention is also applicable to Gunn diodes which generate r.f. energy at a higher harmonic, that is, a multiple of greater than two times the fundamental frequency. The d.c. component would still be greatly diminished resulting in operation at lower power for very little loss of the desired harmonic.

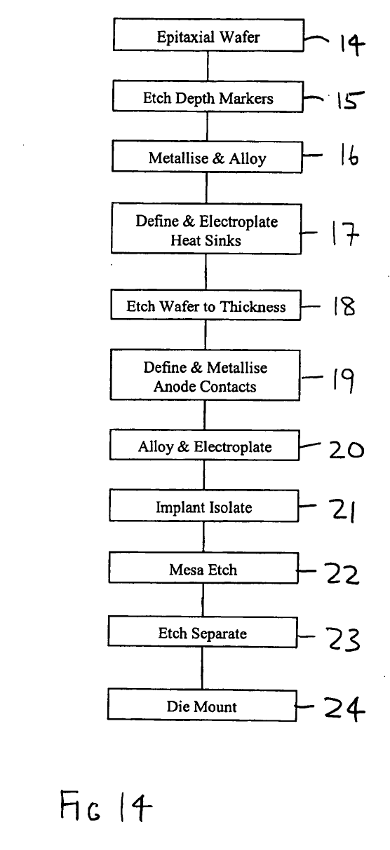

One example of how such Gunn diodes can be manufactured will now be briefly described, with reference to FIGS. 10 to 14.

A gallium arsenide wafer 12 and corresponding to substrate 4 has epitaxial layers corresponding to 5 and 7 to 9 grown on it (step 14) and is metallised over its top surface with gold, and heat sinks 3 corresponding to the heat sink 3 shown in FIG. 1 are electroplated onto the metallised surface (steps 15 to 17). The structure is then etched from the underside to reduce the wafer to a desired thickness (step 18), and the top contacts 2 are produced on the top surface (steps 19,20). Unlike the situation when known Gunn diodes were manufactured when the top contacts 2 were solid discs, in the manufacture of the contacts according to the invention, the top contacts 2 have central apertures. Implant ionisation (step 21) is carried out using the apertured contacts 2 as a mask, in order to render insulating the core region of each Gunn diode being formed. One such Gunn diode is shown in FIGS. 11 and 12, the aperture in the top contact 2 being designated 2a. Etching then takes place (step 22) to produce the tapering mesas, and the mesas are then separated by etching (step 23) to produce the individual Gunn diodes (FIG. 13), and the Gunn diodes are then die mounted (step 24).

Referring to FIG. 15, the Gunn diode shown in FIG. 13 is mounted in a tubular waveguide 26 (rectangular in section), with its heat sink 3 in electrical contact with the wall of the waveguide, which is at ground potential. The contact 2 is connected by two pairs of arms 27 (only one of which is shown in FIG. 15, the other pair being at right angles to the plane of the page thereby forming a cross-shape in plan) to a contact 28, which is supported on the bottom wall of the waveguide as seen in FIG. 15 by an insulating sleeve 29. The contact 28 is in electrical contact with a solid cylindrical resonator 30, which is in electrical contact with a post 31, which is in electrical contact with a disc-shaped section of waveguide 32 which is separated by an annular gap 33 from the remainder of the waveguide 26, in order to be electrically insulated from it.

A dc voltage, typically, 5.5 volts, is applied between the waveguide section 32 and the body of the waveguide to drive the Gunn diode.

The radial disc resonator 30 is resonant at the fundamental frequency of the Gunn diode of FIG. 13, and this frequency is below the cut-off frequency of the waveguide, so oscillations at this frequency are held and cannot be propagated along the waveguide.

The distance between the Gunn diode and the end of the waveguide, forming a backshort, is chosen so that the Gunn diode is also resonant at twice the fundamental frequency, so that electromagnetic radiation at this frequency propagates along the waveguide to the left as seen in FIG. 15.

Structure (not shown) beyond the annular gap 33 is chosen so that this energy cannot leak out through the gap, that is, forming a choke.

A typical frequency for operation of the Gunn diode is around 77 GHz, hence the radial disc 30 must be resonant at around 38.5 GHz. The transit region of the Gunn diode is longer than if the fundamental resonance of the diode was 77 GHz, making it easier to generate the required voltage gradient necessary to sweep the domains through.

Instead of a tubular waveguide, the waveguide may be a microstrip waveguide or a coaxial line. In the case of the microstrip waveguide, the microstrip on a substrate (substrate oscillator) will again have structures resonant at the fundamental and at the desired harmonic. The dimensions of the microstrip will be chosen so that the desired harmonic can propagate along it, but the fundamental cannot propagate along it (such an arrangement is described in British Patent No. 2376140). Such a structure is well suited to operation at harmonics higher than the second, for example, the third or the fourth.

The Gunn diode shown in FIG. 15 is that shown in FIG. 13, but any of the Gunn diodes described herein, such as those in FIGS. 6 to 9, may be used in conjunction with the waveguide of FIG. 15 or in conjunction with any of the other waveguides referred to.

While the invention has been described in relation to a Gunn diode which operates at a second harmonic frequency, the invention is applicable to a Gunn effect current operating at any higher harmonic, that is, any higher multiple of the fundamental.

It will be desirable in some applications for the oscillations to be transmitted in pulses.

The invention has been described in detail with respect to preferred embodiments, and it will now be apparent from the foregoing to those skilled in the art, that changes and modifications may be made without departing from the invention in its broader aspects, and the invention, therefore, as defined in the appended claims, is intended to cover all such changes and modifications that fall within the true spirit of the invention.

What is claimed is:

1. A Gunn diode arranged to be resonant at a fundamental frequency, comprising an elongate portion along which current can flow having contacts at each end, the core of the elongate portion being substantially non-conducting over at least a part of the length of the elongate portion, in which the Gunn diode is also arranged to be resonant at a harmonic of the fundamental frequency

2. A Gunn diode as claimed in claim 1, in which the non-conducting core extends over the entire length of the elongate portion.

3. A Gunn diode as claimed in claim 2, in which the non-conducting core has a maximum diameter within the range of from 50% to 95% of the minimum diameter of the elongate portion.

4. A Gunn diode as claimed in claim 3, in which the non-conducting core has a maximum diameter within the range of from 80% to 90% of the minimum diameter of the elongate portion.

5. A Gunn diode as claimed in claim 1, in which the elongate portion has a hollow core.

6. A Gunn diode as claimed in claim 1, in which the elongate portion includes a core made non-conducting by ion implantation.

7. A Gunn diode as claimed in claim 6, in which the core is made non-conducting by bombardment with ions.

8. A Gunn diode as claimed in claim 7, in which the ions are oxygen ions.

9. A Gunn diode as claimed in claim 7, in which the ions are hydrogen ions.

10. A Gunn diode as claimed in claim 6, in which the ion implantation uses as mask an end contact having an aperture.

11. A Gunn diode arranged to be resonant at a fundamental frequency, comprising an elongate portion along which current can flow having contacts at each end, current flow being confined in use to a strip-like region region over at least a part of the length of the elongate portion, in which the Gunn diode is also arranged to be resonant at a harmonic of the fundamental frequency.

12. A Gunn diode as claimed in claim 11, in which the strip-like region extends in a circumferential direction.

13. A Gunn diode as claimed in claim 11, in which the strip-like region is straight.

14. A Gunn diode as claimed in claim 1, including a resonator resonant at the harmonic of the fundamental frequency.

15. A Gunn diode as claimed in claim 14, including a resonator resonant at the fundamental, arranged so that the resonance at the fundamental is held and not transmitted.

16. A Gunn diode as claimed in claim 15, in which the resonator resonant at the fundamental is arranged in a waveguide structure having dimensions such that the fundamental cannot propagate along it.

17. A Gunn diode as claimed in claim 16, in which the waveguide structure is a tubular waveguide, a microstrip structure, or a coaxial line.

18. A method of fabricating a Gunn diode arranged to be resonant at a harmonic of a fundamental frequency, and having an elongate portion along which current can flow and which has contacts at each end, which comprises the step of producing a non-conducting core over at least a part of the length of the elongate portion.

19. A method as claimed in claim 18, which includes the step of etching a core region.

20. A method as claimed in claim 18, which includes the step of implant isolation to produce the non-conducting core.

21. A method as claimed in claim 20, in which the step of implant isolation comprises bombarding the elongate portion with ions.

22. A method as claimed in claim 21, in which the ions are oxygen ions.

23. A method as claimed in claim 21, in which the ions are hydrogen ions.

24. A method as claimed in claim 20, in which the implant isolation is defined by an apertured mask formed by one of the contacts.

25. A Gunn diode as claimed in claim 11, including a resonator resonant at the harmonic of the fundamental frequency.
